(19) United States
(12) Patent Application Publication
(10) Pub. No.: US 2025/0259766 A1
(43) Pub. Date: Aug. 14, 2025

(54) SUPERCONDUCTING DEVICE WITH MULTIPLE WIRING

(71) Applicant: INTERNATIONAL BUSINESS MACHINES CORPORATION, ARMONK, NY (US)

(72) Inventors: Charlie Tabachnick, Astoria, NY (US); Christian Lavoie, Pleasantville, NY (US); Damon Brooks Farmer, White Plains, NY (US); Marinus Johannes Petrus Hopstaken, Carmel, NY (US); Peter Kerns, Bethel, CT (US); George Gabriel Totir, Newtown, CT (US); Adam M. Pyzyna, Cortlandt Manor, NY (US)

(21) Appl. No.: 18/437,196

(22) Filed: Feb. 8, 2024

(51) Int. Cl. H01B 12/02; C23C 16/40; C23C 16/50; H01B 13/00; H01J 37/32

(52) U.S. Cl. CPC H01B 12/02; C23C 16/402; C23C 16/50; H01B 13/00; H01J 37/3244; H01J 37/32816; H01J 2237/3321

(57) ABSTRACT

A superconducting device includes a first layer, an intermediate layer over the first layer, and a second layer over the intermediate layer. The intermediate layer is configured to decrease strain in the first layer.

### BACKGROUND

### Technical Field

The present disclosure generally relates to superconducting devices, and more particularly, to superconducting devices with multiple wiring structures, and methods of creation thereof.

### Description of the Related Art

For superconductive devices, strain and oxygen ingress are degradation mechanisms. Mismatch between superconductor films and surrounding materials causes crystal lattice strain, lowering critical transition temperature. Oxygen diffusion into films also forms insulating oxides, creating defects and resistive regions. Both strain and oxidation reduce critical performance parameters. Various strategies have been tried to help mitigate degradation.

### SUMMARY

According to an embodiment, a superconducting device includes a first layer, an intermediate layer over the first layer, and a second layer over the intermediate layer. The intermediate layer is configured to decrease strain in the first layer.

In some embodiments, which can be combined with the previous embodiment, the first layer is a metallic layer.

In some embodiments, which can be combined with one or more previous embodiments, the metallic layer includes Niobium (Nb).

In some embodiments, which can be combined with one or more previous embodiments, the second layer includes silicon oxide.

In some embodiments, which can be combined with one or more previous embodiments, the intermediate layer is a silicon-rich layer.

According to an embodiment, a method for fabricating a superconducting device includes forming a first layer, forming an intermediate layer over the first layer, and forming a second layer over the intermediate layer. The intermediate layer is configured to decrease strain in the first layer.

In some embodiments, which can be combined with the previous embodiment, the method includes forming the first layer includes forming a metallic layer. The metallic layer includes Niobium (Nb).

In some embodiments, which can be combined with one or more previous embodiments, forming the intermediate layer includes forming a silicon-rich layer.

In some embodiments, which can be combined with one or more previous embodiments, the method includes flowing a silane gas into a vacuum chamber, and forming the silicon-rich layer over the first layer. The silane gas is flown into the vacuum chamber at a flow rate of about 260 standard cubic centimeter (sccm), and the vacuum chamber is at a temperature of about 400 degrees Celsius.

In some embodiments, which can be combined with one or more previous embodiments, a pressure of the vacuum chamber is about 2.7 Torr, and the silane gas is flown for about 30 seconds to about 120 seconds into the vacuum chamber.

In some embodiments, which can be combined with one or more previous embodiments, forming the second layer includes forming a silicon oxide layer.

In some embodiments, which can be combined with one or more previous embodiments, the method includes simultaneously flowing a silane gas and a nitrous oxide gas into a vacuum chamber, igniting a plasma in the vacuum chamber, and forming the second layer over the intermediate layer.

In some embodiments, which can be combined with one or more previous embodiments, the silane gas is flown into the vacuum chamber at a first flow rate of about 260 standard cubic centimeter (sccm), and the nitrous oxide gas is flown into the vacuum chamber at a second flow rate of about 3900 sccm. The vacuum chamber is at a temperature of about 400 degrees Celsius, and the plasma is ignited at about 300 Watts.

In some embodiments, which can be combined with one or more previous embodiments, a pressure of the vacuum chamber is about 2.7 Torr.

In some embodiments, which can be combined with one or more previous embodiments, the second layer includes silicon oxide.

In some embodiments, which can be combined with one or more previous embodiments, forming the second layer is performed via a plasma-enhanced chemical vapor deposition (PECVD) technique.

According to an embodiment, a superconducting device includes a first layer, an intermediate layer over the first layer, and a second layer over the intermediate layer. The intermediate layer is configured to increase a critical transition temperature of the first layer.

In some embodiments, which can be combined with the previous embodiment, the first layer is a metallic layer.

In some embodiments, which can be combined with one or more previous embodiments, the metallic layer includes Niobium (Nb).

In some embodiments, which can be combined with one or more previous embodiments, the second layer includes silicon oxide.

In some embodiments, which can be combined with one or more previous embodiments, the intermediate layer is a silicon-rich layer.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a conventional superconducting device.

FIG. 2 illustrates a superconducting device, in accordance with some embodiments.

FIGS. 3A-3C illustrate the process of fabricating a superconducting device, in accordance with some embodiments.

FIG. 4 illustrates the effect of silicon oxide deposited on the metal film on the critical temperature of the metal film of the superconducting device, in accordance with some embodiments.

FIG. 5 illustrates a block diagram of a method for forming the superconducting device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “over, “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of an element.

As used herein, the term “vertical” describes an orientation that is arranged perpendicular to the first surface of an element.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconductor,” which are intended to cover functionality that may not be exactly ideal but is within acceptable margins for a given application. For example, a certain level of loss or tolerance may be acceptable such that the resulting materials and structures may still be referred to by these “idealized” terms.

According to an embodiment, a superconducting device includes a first layer, an intermediate layer over the first layer, and a second layer over the intermediate layer. The intermediate layer is configured to decrease strain in the first layer. No further integration changes are required in order to decrease the adverse effects of the strained layer.

In some embodiments, which can be combined with the previous embodiment, the first layer is a metallic layer. The superconducting device can be part of a superconducting device with multiple wiring structure.

In some embodiments, which can be combined with one or more previous embodiments, the metallic layer includes Niobium (Nb). As a superconductor, Nb exhibits zero electrical resistance below its critical temperature. This allows for highly efficient electrical conduction without energy loss, a cornerstone characteristic utilized in a variety of applications, from MRI machines to particle accelerators.

In some embodiments, which can be combined with one or more previous embodiments, the second layer includes silicon oxide. The superconducting device can be part of a superconducting device with multiple wiring structure.

In some embodiments, which can be combined with one or more previous embodiments, the intermediate layer is a silicon-rich layer. The silicon-rich layer can be formed by the silane treatment.

According to an embodiment, a method for fabricating a superconducting device includes forming a first layer, forming an intermediate layer over the first layer, and forming a second layer over the intermediate layer. The intermediate layer is configured to decrease strain in the first layer. No further integration changes are required in order to decrease the adverse effects of the strained layer.

In some embodiments, which can be combined with the previous embodiment, the method includes forming the first layer includes forming a metallic layer. The superconducting device can be part of a superconducting device with multiple wiring structure.

In some embodiments, which can be combined with one or more previous embodiments, the metallic layer includes Niobium (Nb). As a superconductor, Nb exhibits zero electrical resistance below its critical temperature. This allows for highly efficient electrical conduction without energy loss, a cornerstone characteristic utilized in a variety of applications, from MRI machines to particle accelerators.

In some embodiments, which can be combined with one or more previous embodiments, forming the intermediate layer includes forming a silicon-rich layer. The silicon-rich layer can be formed by the silane treatment.

In some embodiments, which can be combined with one or more previous embodiments, the method includes flowing a silane gas into a vacuum chamber, and forming the silicon-rich layer over the first layer. The silane treatment can form the intermediate layer, which can reduce the strain in the metallic layer.

In some embodiments, which can be combined with one or more previous embodiments, the silane gas is flown into the vacuum chamber at a flow rate of about 260 standard cubic centimeter (sccm), and the vacuum chamber is at a temperature of about 400 degrees Celsius. Such reaction conditions facilitate the formation of the intermediate layer.

In some embodiments, which can be combined with one or more previous embodiments, a pressure of the vacuum chamber is about 2.7 Torr, and the silane gas is flown for about 30 seconds to about 120 seconds into the vacuum chamber. Such reaction conditions facilitate the formation of the oxide layer.

In some embodiments, which can be combined with one or more previous embodiments, forming the second layer includes forming a silicon oxide layer. The superconducting device can be part of a superconducting device with multiple wiring structure.

In some embodiments, which can be combined with one or more previous embodiments, the method includes simultaneously flowing a silane gas and a nitrous oxide gas into a vacuum chamber, igniting a plasma in the vacuum chamber, and forming the second layer over the intermediate layer. Thus, the second layer is formed over the intermediate layer formed from the silane gas and nitrous gas flow.

In some embodiments, which can be combined with one or more previous embodiments, the silane gas is flown into the vacuum chamber at a first flow rate of about 260 standard cubic centimeter (sccm), and the nitrous oxide gas is flown into the vacuum chamber at a second flow rate of about 3900 sccm. Such reaction conditions facilitate the formation of the intermediate layer.

In some embodiments, which can be combined with one or more previous embodiments, the vacuum chamber is at a temperature of about 400 degrees Celsius, and the plasma is ignited at about 300 Watts. Such reaction conditions facilitate the formation of the intermediate layer.

In some embodiments, which can be combined with one or more previous embodiments, a pressure of the vacuum chamber is about 2.7 Torr. Such reaction conditions facilitate the formation of the intermediate layer.

In some embodiments, which can be combined with one or more previous embodiments, the second layer includes silicon oxide. The superconducting device can be part of a superconducting device with multiple wiring structure.

In some embodiments, which can be combined with one or more previous embodiments, forming the second layer is performed via a plasma-enhanced chemical vapor deposition (PECVD) technique. Utilizing the PECVD ensures the formation of a uniform intermediate layer over the metallic layer.

According to an embodiment, a method for forming a superconducting device includes forming an intermediate layer over a first layer via an in-situ silane treatment in a vacuum chamber, annealing the superconducting device, and forming a second layer over the intermediate layer. No further integration changes are required in order to decrease the adverse effects of the strained layer.

The concepts herein relate to superconducting devices. superconducting devices such as sensors, filters, and quantum computing elements can utilize complex wiring patterns constructed from stacked layers of thin superconductor films such as niobium or yttrium barium copper oxide. These multilayer structures include intricate arrangements of superconductor wires, transmission lines, and interconnects integrated vertically in a 3D configuration. Multiple levels of wiring, often separated by dielectric layers, enable high-density integration of complex electrical circuits and components within a compact footprint. Careful fabrication using processes such as chemical vapor deposition and lithography allow precision patterning and deposition of the superconductor layers as well as the insulating dielectric films separating each level. Contact vias and plugs facilitate electrical connections between the wiring levels.

Maintaining superconductivity and reliable connections across this integrated stack remains an engineering challenge, especially as more layers are added. Issues like strain, adhesion, alignment, and thermal management must be addressed through structural and process optimizations.

Plasma-enhanced chemical vapor deposition (PECVD) is a process used to deposit thin films from a gas state to a solid state on a substrate. For instance, PECVD can be utilized to deposit a film of silicon dioxide (SiO2) onto a substrate made of niobium (Nb). Niobium is a superconductor metal, which loses all electrical resistance when cooled below its critical transition temperature. This allows niobium to conduct electricity with zero loss when in the superconductor state. The superconducting device can use multiple layered niobium wiring to take advantage of niobium's superconductivity for lossless power transmission.

However, when depositing the SiO2 film onto the niobium using PECVD, two problematic effects occur: i) strain is induced in the niobium, and ii) oxygen from the SiO2 layer ingresses/diffuses into the niobium metal. Strain and oxygen ingress can be major degradation mechanisms affecting the superconducting device's performance. Structural mismatch between the niobium and surrounding materials induce strain in the superconductor crystal lattice, altering interatomic spacing and electron transport properties of the superconducting device. This mismatch can drastically lower critical transition temperature and critical current density. Additionally, niobium readily oxidizes when exposed to oxygen at elevated temperatures. Diffusion of oxygen into the superconductor from adjacent oxide layers during processing forms insulating metal oxide phases within the superconductor film, creating defects and nucleation sites for resistive regions, also lowering transition temperature through chemical alteration and crystal structure damage. These strain and oxidation effects reduce electrical and superconductor performance critical for superconducting device's functionality.

The combination of this strain and oxygen infiltration from the SiO2 deposition severely degrades the superconductor properties of the niobium. Specifically, the critical transition temperature, i.e., the crucial temperature threshold below which niobium becomes superconductor, is drastically reduced. This reduction makes it more difficult to practically utilize the niobium in superconductor circuitry and wiring, (e.g., below temperatures attainable with standard cooling techniques).

There are some alternative approaches that could potentially remedy these problems:

1—Using electron beam physical vapor deposition to evaporate and deposit the SiO2. This approach could provide limited conformal coverage but avoid issues with strain and oxygen infiltration. However, the deposited SiO2 may not fully cover complex device geometries.

2—Thermal CVD of SiO2 which utilizes higher temperature chemistry to deposit the oxide, avoiding plasma damage and resulting in better quality films. However, the required higher temperatures may not be compatible with prior or subsequent nanofabrication steps for the Nb devices.

3—Completely alternative dielectric materials could be explored, but this approach involves developing and optimizing entirely new device integration schemes and processes around the different chemical, structural, and electrical characteristics of those dielectrics.

The disclosed superconducting device offers a simple approach to tackle the problems outlined, without needing extensive changes to existing device integration. The disclosed superconducting device utilizes an in-situ silane (SiH4) treatment during a process step before PECVD of SiO2 onto Nb films, which eliminates strain in the Nb while avoiding oxygen diffusion into the Nb layers even at elevated process temperatures. Specifically, the Nb critical transition temperature is maintained near the as-deposited Nb value, resulting in negligible strain and oxygen defects induced by the subsequent modified SiO2 deposition process. Therefore, SiO2 can successfully be integrated onto Nb films for the disclosed superconducting device without degrading device performance, allowing continued use of existing integration schemes. The fabrication process of the disclosed superconductive device avoids changing tooling, materials, geometry, or designs thus enabling a simple implementation.

Accordingly, the teachings herein provide methods and systems for fabricating a superconductive device. The techniques described herein may be implemented in a number of ways. Example implementations are provided below with reference to the following figures.

Example Superconducting Device with Multiple Wiring Structure

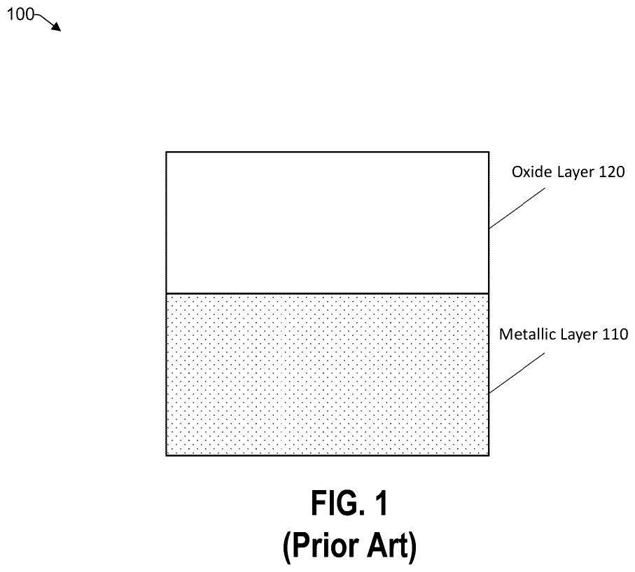

Reference is now made to FIG. 1, which is a schematic illustration of the conventional superconducting device with multiple wiring. In a conventional superconducting device with multiple wirings 100, a layer of a silicon oxide, SiO2 110, is formed directly over a conductive layer, Nb layer, 120. It should be noted that, the SiO2 110 and the Nb layer 120 would interact as part of a larger system. The SiO2 110 can provide insulation between different superconducting wires to prevent electrical cross-talk and ensure independent operation of multiple circuit paths. Meanwhile, the Nb layer 120 can be part of the superconducting wires itself, or it can serve as a base upon which additional superconducting films are deposited to create the multiple wiring pathways necessary for superconducting circuits. Such superconducting wires can be responsible for carrying current with no loss, which is the primary advantage of superconducting devices over traditional semiconductor-based electronics. However, as mentioned above, the Nb layer 120 can be strained due to the existence of dissolved oxygen.

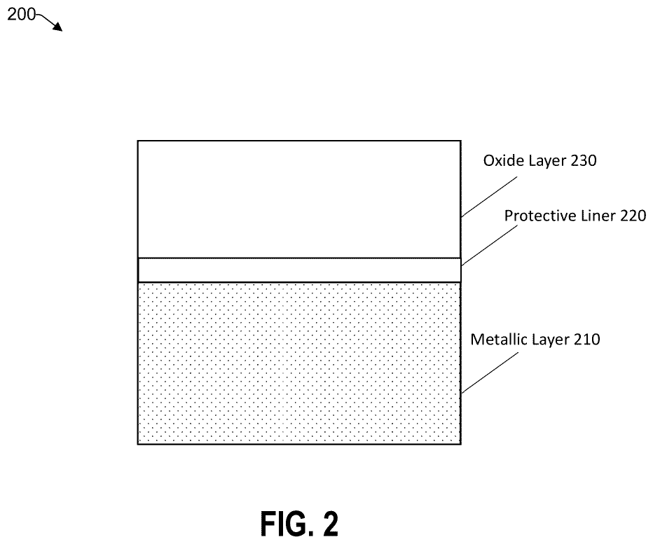

Reference is now made to FIG. 2, which is a schematic illustration of a superconducting device with multiple wiring, in accordance with some embodiments. The superconducting device 200 can include a metallic layer 210, a protective liner 220, sometimes referred to as a protective layer, over the metallic layer 210, and an oxide layer 230 over the protective liner 220. Thus, in contrast to the conventional superconducting devices, such as the superconducting device shown in FIG. 1, the metallic layer 210 is not directly in contact with the oxide layer 230. The protective liner 220 separates, i.e., isolates, the metallic layer 210 and the oxide layer 230. As mentioned above, the protective liner 220 can reduce the strain in the metallic layer 210. In some embodiments, the protective liner 220 can increase the critical transition temperature, Tc, of the metallic layer 210. Tc is the temperature threshold at which the metallic layer 210 transitions from a normal resistive state into a superconducting state whereby it exhibits near zero electrical resistance and near perfect diamagnetism.

In some embodiments, the metallic layer 210 is made of Niobium, Nb. As a superconductor, Nb exhibits zero electrical resistance below its critical temperature, and allows for highly efficient electrical conduction without energy loss. In some embodiments, the metallic layer 210 exhibits a high critical magnetic field, allowing it to maintain its superconducting state even in the presence of strong magnetic fields. While Nb is shown as the metallic layer 210, in some embodiments, other superconducting metals with columnar grain that makes prone to oxygen diffusion can be used as the metallic layer 210. In some embodiments, Ta, Al, V, Ti and Ru can be used as the metallic layer 210.

In some embodiments, the oxide layer 230 is made of silicon dioxide, SiO2, and acts as an insulator, providing electrical isolation for the superconducting components below it, e.g., the metallic layer 210. The oxide layer 230 can further define the pathways for the superconducting currents and ensure that these pathways do not interfere with each other. Additionally, the oxide layer 230 serves as a dielectric material within the superconducting circuit's capacitors, crucial for controlling the circuit's resonant frequencies and capacitance. The oxide layer 230 also provides a protective shield for the metallic layer 210, i.e., niobium, preventing its oxidation and contamination which can adversely affect superconductivity. During the fabrication of superconducting circuits, the oxide layer 230 is instrumental as a mask in lithography processes, helping to define the precise geometry of niobium circuits through selective etching. The thermal stability of the oxide layer 230 ensures that the superconducting device 200 maintains its integrity when subjected to the high temperatures often used in manufacturing processes. Furthermore, as a chemical barrier, the oxide layer 230 prevents unwanted diffusion of atoms into the niobium layer, preserving the purity of the niobium's superconducting properties.

The protective liner 220 can serve as a barrier protecting the underlying materials, i.e., the metallic layer 210, from contamination or damage during processing and operation. The protective liner 220 can further help mitigate the diffusion of substances from the adjacent layers, and preserve the integrity of the metallic layer 210 and its properties. While FIG. 2 and other figures illustrate a superconducting device with multiple wiring, it should be noted that the application of the disclosed superconducting device can be expanded to any other superconducting devices that rely on the control of the critical transition temperature. As a non-limiting example, the disclosed superconducting device can be used to flux control for digital integrated circuits, and superconducting quantum interference device (SQUIDs). Furthermore, embodiments of the disclosed superconducting device can have secondary effects on the metallic layer which can include strain reduction and room temperature resistivity improvement. Such secondary effects can be useful for non-superconducting applications such as conventional wiring structures for digital circuits.

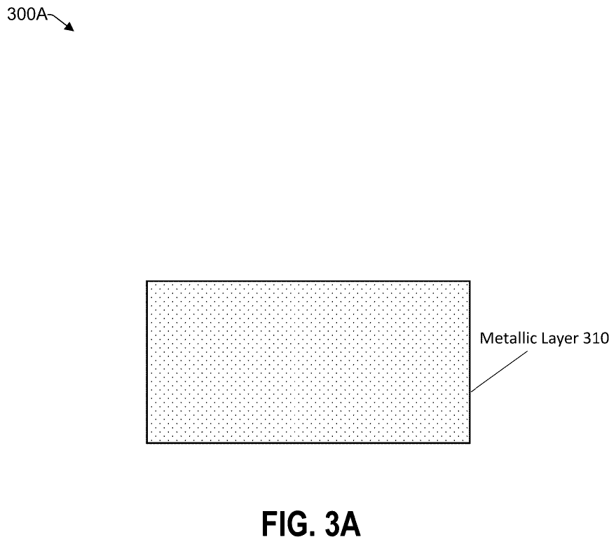

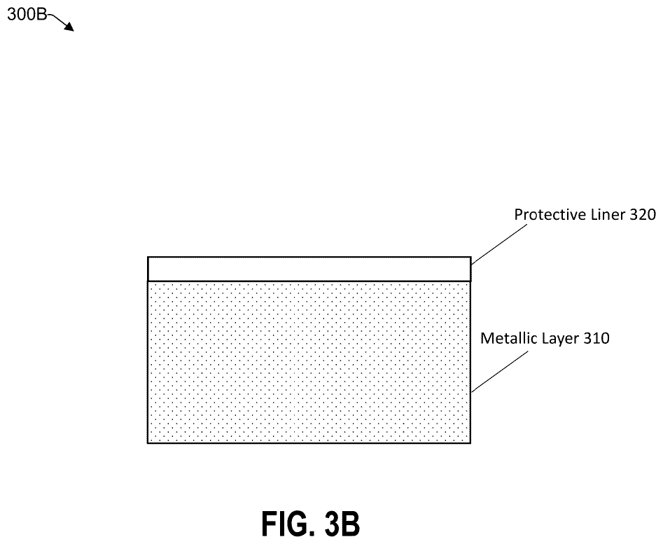

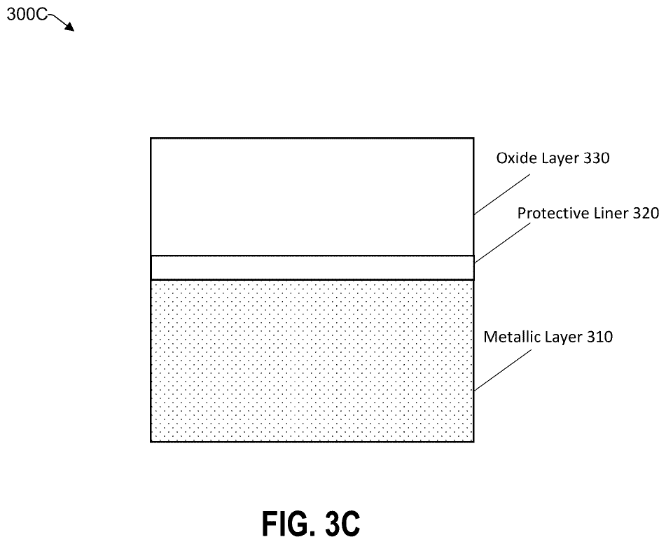

FIGS. 3A-3C are schematic illustrations of the process of making a superconducting device, in accordance with some embodiments. Referring is now made to FIG. 3A, which illustrates a superconducting device 300A after a metal layer is deposited, in accordance with some embodiments. In some embodiments, the metal layer 310 is deposited over a substrate (not shown). The metal layer 310 can be used as a substrate for further processing. The metal layer 310 is an unstrained layer, since the crystal lattice of the metal layer 310 is free from distortion caused by any other material being deposited over the metal layer 310.

FIG. 3B illustrates a superconducting device 300B after the formation of the protective liner over, in accordance with some embodiments. In some embodiments, a protective liner 320 is formed over the metal layer 310.

The protective liner 320 can be formed using an in-situ treatment by silane gas (SiH4). In some embodiments, the silane treatment process is performed at the temperature of about 400° C. and about 2.7 Torr and at a flow rate of about 260 standard cubic centimeter (sccm). The in-situ silane treatment process can be conducted at a pressure of 2.7 Torr to enhance the quality and uniformity of the silicon layer being deposited. As a result, the protective liner 320 is a silicon-rich layer. In various embodiments, the silane gas is flown for about 30 seconds to about 120 seconds into the vacuum chamber.

At the elevated temperature, such as at 400° C., the silane gas breaks down into silicon and hydrogen atoms in a reaction known as pyrolysis. The silicon atoms deposit onto the substrate, i.e., the metal layer 310, forming a thin layer of silicon, the protective liner 320, while the hydrogen atoms help to passivate the surface of the metal layer 310, and terminate dangling bonds that can introduce unwanted electronic states. Such a high-temperature treatment process can ensure that the protective liner 320 is of high purity and quality, which enhances the performance of superconducting device. In some embodiments, the temperature, e.g., about 400° C., is sufficiently high to allow for deposition of silicon, but not so high as to cause excessive diffusion of silicon into the metal layer 310, which could degrade the material properties essential for superconductivity.

In some embodiments, the low pressure of about 2.7 Torr helps to control the rate of deposition and allows for the fine-tuning of the film's thickness and other characteristics. By lowering the pressure to about 2.7 Torr, the mean free path of the silane gas molecules is increased, which leads to a more line-of-sight deposition, which in turn can improve the uniformity and smoothness of the protective liner 320.

The in-situ silane treatment process can be carried out in the same chamber as other acts in the device fabrication process, e.g., the metal deposition act as illustrated in FIG. 3A. In other words, the metal layer 310 does not have to be moved between different equipment setups, which reduces the risk of contamination and ensures adherence of the protective liner 320 to the metal layer 310. Keeping the metal layer 310 in a controlled environment from one process step to the next is help the integrity of the superconducting device, especially when creating layers that are only a few atoms thick.

In some embodiments, the protective liner 320 can act as a barrier against environmental contamination, protect the metal layer 310 during subsequent fabrication processes, and can also prevent the diffusion of other materials into the metal layer 310 that could potentially alter its superconducting properties.

FIG. 3C illustrates a superconducting device 300C after the formation of the oxide layer over the protective liner 320, in accordance with some embodiments. In some embodiments, the oxide layer 330 is deposited directly over the protective liner 320. The oxide layer 330 can be silicon dioxide (SiO2) and acts as an insulating material to isolate the superconducting current paths electrically. The oxide layer 330 can ensure that each superconducting path in a multiple wiring superconducting device is well-defined and separated from others to avoid electrical interference. Additionally, the oxide layer 330 can help in defining the architecture of the superconducting device through various lithographic and etching processes.

In some embodiments, the oxide layer 330 is deposited by utilizing a PECVD technique, which deposits thin films of an oxide material, e.g., SiO2, from a gas state to a solid state on a substrate, e.g., the protective liner 320. In some embodiments, the PECVD is used to deposit silicon dioxide (SiO2) at a temperature of about 400° C., a pressure of about 2.7 Torr, with a power of about 300 W using silane (SiH4) and nitrous oxide (N2O) as precursors. The silane can be flown at a flowrate of about 260 sccm and the nitrous oxide can be flown at a flowrate of about 3900 sccm.

At a deposition temperature of about 400° C., the disclosed PECVD technique utilizes plasma to enhance the chemical reactions. This plasma is generated by applying about 300 W of power to the process gas mixture, i.e., SiH4 and N2O. In some embodiments, by lowering the temperature, the compatibility with substrates, that cannot withstand higher temperatures, is enhanced.

In some embodiments, the pressure of about 2.7 Torr helps to regulate the density and flow of the reactant gases in the chamber, which is a balance between enough pressure to sustain the plasma, and low enough to allow for uniform gas-phase reactions and film deposition. At this pressure of about 2.7 Torr, the mean free path of the gas molecules is longer, which can aid in a more uniform deposition over the substrate.

In some embodiments, the precursors, i.e., SiH4 and N2O, react in the plasma environment to form SiO2 as the oxide layer 330. The plasma provides the energy needed to break the molecular bonds in the SiH4 and N2O gases. The silicon atoms from the SiH4 combine with the oxygen atoms from both the SiH4 and N2O to form the SiO2 film. In various embodiments, the additional nitrogen and oxygen from the N2O form nitrogen gas (N2) and oxygen gas (O2), which are pumped away. In some embodiments, the silane gas flow is stopped upon the formation of the protective liner 320, as shown in FIG. 3B, and is resumed for the formation of the oxide layer 330, as shown in FIG. 3C. Alternatively, in some embodiments, the silane gas is continuously flown into the chamber during the formation of the protective liner 320, as shown in FIG. 3B, and the formation of the oxide layer 330 is completed, as shown in FIG. 3C.

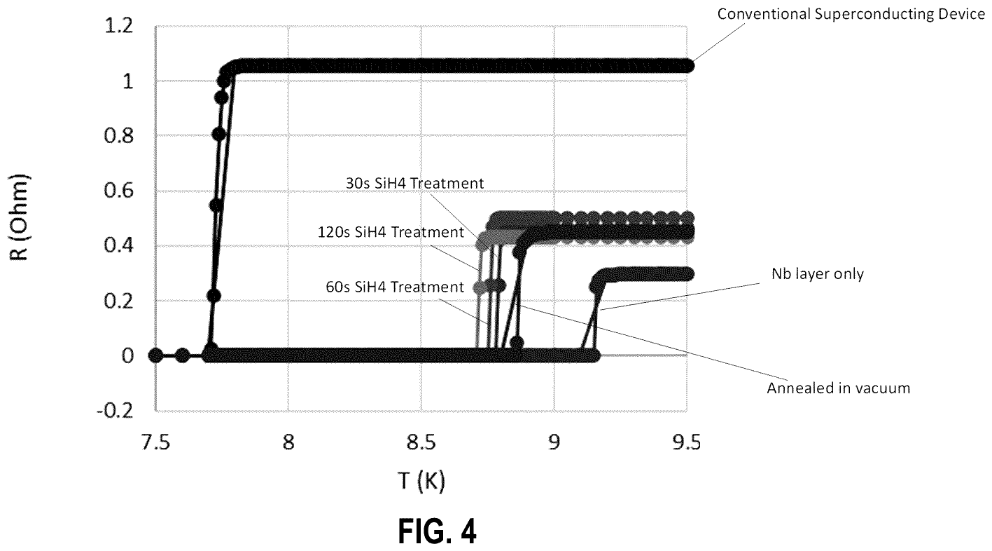

FIG. 4 illustrates the effect of silicon oxide deposited on the metal film on the critical temperature of the metal film of the superconducting device, in accordance with some embodiments. As can be seen, the critical temperature (Tc) of the superconducting device changes substantially with the time duration at which the silane gas flows in the vacuum chamber. In other words, Tc is directly correlated with the thickness of the protective liner over the metal layer.

In some embodiments, upon the formation of the metal layer, i.e., in the absence of the oxide layer, the superconducting device is annealed. The annealing process can take place for about 45 seconds at about 400° C. and a pressure of about 1 milli Torr. Results of the annealed superconductor device can show an upper limit for Tc based on thermally induced effects from the PECVD chamber. As shown, the annealed superconducting device possesses enhanced Tc compared to the non-annealed superconducting devices and the superconducting devices in the presence of the oxide layer and the protective liner. The “as deposited” superconducting device, i.e., without the oxide layer and the protective liner, and the conventional superconducting device are depicted as references. In some embodiments, the in-situ silane treatment forms a NbSiₓO_{y} over the metal layer. The NbSiₓO_{y} can have a thickness of about 1 nanometer to about 6 nanometers, where the Nb layer has a thickness of about 200 nanometers.

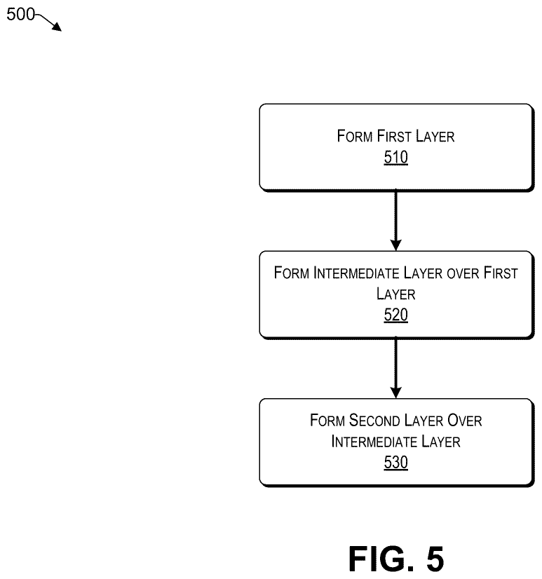

FIG. 5 illustrates a block diagram of method 500 for fabricating a superconducting device, in accordance with some embodiments. As shown by block 510, a first layer is formed.

As shown by block 520, an intermediate layer is formed over the first layer.

As shown by block 530, a second layer is formed over the intermediate layer. The intermediate layer can decrease strain in the first layer.

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A superconducting device, comprising:
a first layer;
an intermediate layer over the first layer; and
a second layer over the intermediate layer, wherein the intermediate layer is configured to decrease strain in the first layer.

2. The superconducting device of claim 1, wherein the first layer is a metallic layer.

3. The superconducting device of claim 2, wherein the metallic layer includes Niobium (Nb).

4. The superconducting device of claim 1, wherein the second layer includes silicon oxide.

5. The superconducting device of claim 1, wherein the intermediate layer is a silicon-rich layer.

6. A method for fabricating a superconducting device, the method comprising:
forming a first layer;
forming an intermediate layer over the first layer; and
forming a second layer over the intermediate layer, wherein the intermediate layer is configured to decrease strain in the first layer.

7. The method of claim 6, wherein forming the first layer comprises forming a metallic layer, and wherein the metallic layer includes Niobium (Nb).

8. The method of claim 6, wherein forming the intermediate layer comprises forming a silicon-rich layer.

9. The method of claim 8, further comprising:
flowing a silane gas into a vacuum chamber; and
forming the silicon-rich layer over the first layer,
wherein the silane gas is flown into the vacuum chamber at a flow rate of about 260 standard cubic centimeter (sccm), and wherein the vacuum chamber is at a temperature of about 400 degrees Celsius.

10. The method of claim 9, wherein a pressure of the vacuum chamber is about 2.7 Torr, and wherein the silane gas is flown for about 30 seconds to about 120 seconds into the vacuum chamber.

11. The method of claim 6, wherein forming the second layer comprises forming a silicon oxide layer.

12. The method of claim 11, further comprising:
simultaneously flowing a silane gas and a nitrous oxide gas into a vacuum chamber;
igniting a plasma in the vacuum chamber; and
forming the second layer over the intermediate layer.

13. The method of claim 12, wherein the silane gas is flown into the vacuum chamber at a first flow rate of about 260 standard cubic centimeter (sccm), and the nitrous oxide gas is flown into the vacuum chamber at a second flow rate of about 3900 sccm, wherein the vacuum chamber is at a temperature of about 400 degrees Celsius, and wherein the plasma is ignited at about 300 Watts.

14. The method of claim 12, wherein a pressure of the vacuum chamber is about 2.7 Torr.

15. The method of claim 6, wherein forming the second layer is performed via a plasma-enhanced chemical vapor deposition (PECVD) technique.

16. A superconducting device, comprising:
a first layer;
an intermediate layer over the first layer; and
a second layer over the intermediate layer, wherein the intermediate layer is configured to increase a critical transition temperature of the first layer.

17. The superconducting device of claim 16, wherein the first layer is a metallic layer.

18. The superconducting device of claim 17, wherein the metallic layer includes Niobium (Nb).

19. The superconducting device of claim 16, wherein the second layer includes silicon oxide.

20. The superconducting device of claim 16, wherein the intermediate layer is a silicon-rich layer.
